(19) United States
(12) Patent Application Publication
(10) Pub. No.: US 2025/0029895 A1
(43) Pub. Date: Jan. 23, 2025

(54) SEMICONDUCTOR STACKED STRUCTURE AND SEMICONDUCTOR PACKAGE INCLUDING THE SAME

(71) Applicant: SAMSUNG ELECTRONICS CO., LTD., Suwon-si (KR)

(72) Inventor: Seungduk BAEK, Suwon-si (KR)

(73) Assignee: SAMSUNG ELECTRONICS CO., LTD., Suwon-si (KR)

(21) Appl. No.: 18/435,414

(22) Filed: Feb. 7, 2024

(30) Foreign Application Priority Data
Jul. 19, 2023 (KR) 10-2023-0094019

(51) Int. Cl. H01L 23/48; H01L 23/00; H01L 23/31; H01L 23/538; H01L 25/065; H10B 80/00

(52) U.S. Cl. CPC H01L 23/481; H01L 23/3107; H01L 23/5384; H01L 23/5385; H01L 24/16; H01L 24/32; H01L 24/73; H01L 25/0657; H10B 80/00; H01L 2224/16145; H01L 2224/32145; H01L 2224/73204

(57) ABSTRACT

A semiconductor stacked structure includes a first semiconductor chip including, a central region, an outer region at least partially surrounding the central region, the outer region including a corner region, and a first through-electrode in the central region, a plurality of second semiconductor chips sequentially stacked in the central region and connected to the first semiconductor chip, each of the plurality of second semiconductor chips including a second through-electrode, and at least one passive device in the corner region of the outer region.

### CROSS-REFERENCE TO RELATED APPLICATION

This application is based on and claims priority under 35 U.S.C. § 119 to Korean Patent Application No. 10-2023-0094019, filed on Jul. 19, 2023, in the Korean Intellectual Property Office, the disclosure of which is incorporated by reference herein in its entirety.

### BACKGROUND

Example embodiments of the disclosure relate to a semiconductor stacked structure and a semiconductor package including the semiconductor stacked structure.

Electronic devices are multi-functional, more compact and have high capacity according to the rapid development of the electronics industry and user demands. Accordingly, multiple semiconductor chips may be mounted on a semiconductor package that is mounted on an electronic device to improve performance or increase capacity of the semiconductor package. However, in electronic devices including semiconductor packages, power delivery noise may occur during high-speed operation.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor stacked structure that may transmit high-speed signals without noise, and a semiconductor package including the same.

Additional aspects will be set forth in part in the description which follows and, in part, will be apparent from the description, or may be learned by practice of the presented embodiments.

According to an aspect of an example embodiment, a semiconductor stacked structure may include a first semiconductor chip including, a central region, an outer region at least partially surrounding the central region, the outer region including a corner region, and a first through-electrode in the central region, a plurality of second semiconductor chips sequentially stacked in the central region and connected to the first semiconductor chip, each of the plurality of second semiconductor chips including a second through-electrode, and at least one passive device in the corner region of the outer region.

According to an aspect of an example embodiment, a semiconductor stacked structure may include a first semiconductor chip including a central region, an outer region at least partially surrounding the central region, the outer region including a corner region, and a plurality of first through-electrodes in the central region and penetrating the first semiconductor chip, a plurality of second semiconductor chips sequentially stacked on the first semiconductor chip in the central region and connected to the first semiconductor chip, each of the plurality of second semiconductor chips including a second semiconductor substrate, and a plurality of second through-electrodes penetrating the second semiconductor substrate and respectively connected to the plurality of first through-electrodes, at least one passive device in the corner region of the outer region, and a chip molding layer on the first semiconductor chip and at least partially surrounding the plurality of second semiconductor chips.

According to an aspect of an example embodiment, a semiconductor package may include a package base substrate, an interposer on the package base substrate and connected to the package base substrate, the interposer including a base layer and a plurality of interposer through-electrodes penetrating the base layer, at least one semiconductor stacked structure on the interposer, the at least one semiconductor stacked structure including a first semiconductor chip including a central region, an outer region at least partially surrounding the central region, the outer region including a corner region, and a first through-electrode in the central region, a plurality of second semiconductor chips sequentially stacked on the first semiconductor chip in the central region and connected to the first semiconductor chip, each of the plurality of second semiconductor chips including a second through-electrode, at least one passive device in the corner region of the outer region, and a chip molding layer on an upper surface of the first semiconductor chip and at least partially covering side surfaces of the plurality of second semiconductor chips, at least one third semiconductor chip on the interposer and horizontally spaced apart from the at least one semiconductor stacked structure, and a package molding layer on the interposer and at least partially surrounding the at least one semiconductor stacked structure and the at least one third semiconductor chip, where the package molding layer is configured to form a molding interface with the chip molding layer.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view illustrating a semiconductor package according to one or more embodiments;

FIG. 2 is a cross-sectional view illustrating a semiconductor stacked structure according to one or more embodiments;

FIG. 3 is a plan view illustrating a semiconductor stacked structure according to one or more embodiments;

FIG. 4 is a partially enlarged view illustrating a modified example of the semiconductor stacked structure of FIG. 2 according to one or more embodiments;

FIG. 5 is a partially enlarged view illustrating a modified example of the semiconductor stacked structure of FIG. 2 according to one or more embodiments;

FIG. 6 is a cross-sectional view illustrating a semiconductor package according to one or more embodiments;

FIGS. 7A to 7F are cross-sectional views illustrating a method of manufacturing a semiconductor stacked structure, according to one or more embodiments; and

FIG. 8 is a block diagram illustrating an example of a memory system including a semiconductor package, according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

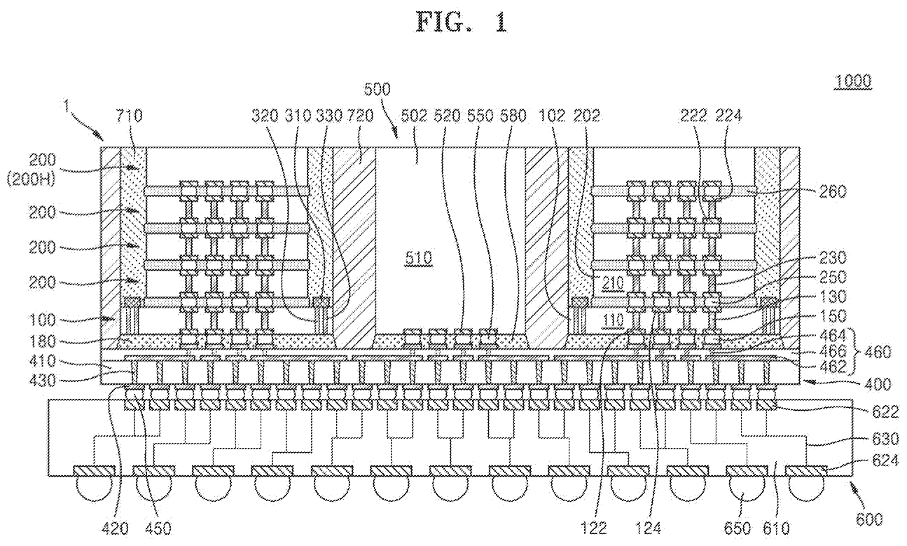

FIG. 1 is a cross-sectional view illustrating a semiconductor package according to one or more embodiments.

Referring to FIG. 1, a semiconductor package 1000 may include a package base substrate 600, an interposer 400 attached to the package base substrate 600, a semiconductor stacked structure 1 attached to the interposer 400, and a third semiconductor chip 500 attached to the interposer 400. The semiconductor stacked structure 1 may include a first semiconductor chip 100, a plurality of second semiconductor chips 200 stacked on the first semiconductor chip 100, and a passive device 310 on the first semiconductor chip 100. The semiconductor stacked structure 1 and the third semiconductor chip 500 may be spaced apart from each other in the horizontal direction and may be attached to the interposer 400. The third semiconductor chip 500 may be a logic semiconductor chip including a semiconductor device, such as a logic device.

Although FIG. 1 illustrates that the semiconductor package 1000 includes two semiconductor stacked structures 1 and one third semiconductor chip 500 attached to the interposer 400, the semiconductor package 1000 is not limited thereto. The semiconductor package 1000 may include, for example, one, two, four, six, eight, or more semiconductor stacked structures 1. The semiconductor package 1000 may include, for example, one, two, four, six, eight, or more third semiconductor chips 500.

The package base substrate 600 may include a base substrate layer 610, a plurality of substrate upper surface pads 622 on an upper surface of the base substrate layer 610, and a plurality of substrate lower surface pads 624 on a lower surface of the base substrate layer 610. The package base substrate 600 may include a plurality of substrate wiring paths 630 that electrically and respectively connect the plurality of substrate upper surface pads 622 to the plurality of substrate lower surface pads 624 through the base substrate layer 610. In some embodiments, the package base substrate 600 may be a printed circuit board. For example, the package base substrate 600 may be a multi-layer printed circuit board.

The base substrate layer 610 may be formed of at least one material of phenol resin, epoxy resin, and polyimide. For example, the base substrate layer 610 may include at least one material of frame retardant 4 (FR4), tetrafunctional epoxy, polyphenylene ether, epoxy/polyphenylene oxide, bismaleimide triazine (BT), thermount, cyanate ester, polyimide, and liquid crystal polymer. In some embodiments, the base substrate layer 610 may be formed of, for example, polyester (PET), polyester telephthalate, fluorinated ethylene propylene (FEP), resin coated paper, liquid polyimide resin, a polyethylene naphthalate (PEN) film, etc. The base substrate layer 610 may be formed by stacking a plurality of base layers.

The plurality of substrate upper surface pads 622 and the plurality of substrate lower surface pads 624 may each be formed of copper, nickel, stainless steel, or beryllium copper. For example, the plurality of substrate upper surface pads 622 and the plurality of substrate lower surface pads 624 may each be formed of plated copper. In some embodiments, surface portions of the plurality of substrate upper surface pads 622 and the plurality of substrate lower surface pads 624 on the opposite side of the base substrate layer 610 may include Ni/Au, etc.

The plurality of substrate wiring paths 630 may include a plurality of buried conductive layers extending in the horizontal direction and a plurality of conductive vias extending in the vertical direction. The plurality of conductive vias may connect two buried conductive layers among the plurality of buried conductive layers that are at different vertical levels, the plurality of substrate upper surface pads 622, and the plurality of substrate lower surface pads 624. The plurality of substrate wiring paths 630 may each be formed of, for example, electrolytically deposited (ED) copper, rolled-annealed (RA) copper foil, stainless steel foil, aluminum foil, ultra-thin copper foil, sputtered copper, copper alloys, nickel, stainless steel, beryllium copper, etc.

The base substrate layer 610 may further include solder resist layers respectively exposing the plurality of substrate upper surface pads 622 and the plurality of substrate lower surface pads 624 on an upper surface and a lower surface of the base substrate layer 610. The solder resist layers may each be formed of a polyimide film, a polyester film, a flexible solder mask, a photo-imageable coverlay (PIC), a photo-imageable solder resist, etc. The solder resist layers may be formed by heat-curing the thermosetting ink applied by, for example, a silk screen printing method or an inkjet method. The solder resist layers may be formed by, for example, removing a portion of the photosensitive solder resist applied by a screen method or a spray coating method through exposure and development, and then by heat-curing the photosensitive solder resist. The solder resist layers may be formed by laminating, for example, a polyimide film or polyester film.

A plurality of interposer connection terminals 450 may be respectively connected to the plurality of substrate upper surface pads 622, and a plurality of external connection terminals 650 may be respectively connected to the plurality of substrate lower surface pads 624. The plurality of interposer connection terminals 450 may electrically connect the interposer 400 to the package base substrate 600. The plurality of external connection terminals 650 respectively connected to the plurality of substrate lower surface pads 624 may connect the semiconductor package 1000 to an external device. In some embodiments, the plurality of interposer connection terminals 450 and the plurality of external connection terminals 650 may each be a bump, a solder ball, etc.

The interposer 400 may be used to implement, in a fine pitch type, a connection terminal for connecting the semiconductor stacked structure 1 and the third semiconductor chip 500 to the package base substrate 600. The interposer 400 may include a base layer 410, a plurality of interposer lower surface pads 420 on a lower surface of the base layer 410, a plurality of interposer through-electrodes 430 penetrating the base layer 410 to connect an upper surface of the base layer 410 to the lower surface of the base layer 410, and an interposer wiring structure 460 on the upper surface of the base layer 410. A plurality of interposer connection terminals 450 may be respectively attached to the plurality of interposer lower surface pads 420. The plurality of interposer connection terminals 450 may be respectively between the plurality of substrate upper surface pads 622 and the plurality of interposer lower surface pads 420 to electrically connect the interposer 400 to the package base substrate 600.

The base layer 410 may include a semiconductor material, glass, ceramic, or plastic. For example, the base layer 410 may include silicon. In some embodiments, the interposer 400 may be a silicon (Si) interposer including the base layer 410 formed from a silicon semiconductor substrate.

The plurality of interposer through-electrodes 430 may each include a conductive plug penetrating the base layer 410 and a conductive barrier layer surrounding or at least partially surrounding the conductive plug. The conductive plug may include Cu or W, and the conductive barrier layer may include a metal or conductive metal nitride. The conductive plug may have a cylindrical shape, and the conductive barrier layer may have a cylindrical shape surrounding or at least partially surrounding a sidewall of the conductive plug. A plurality of via insulating layers may be between the base layer 410 and the plurality of interposer through-electrodes 430 to surround or at least partially surround sidewalls of the plurality of interposer through-electrodes 430. The plurality of via insulating layers may prevent the base layer 410 from directly contacting the plurality of interposer through-electrodes 430. The via insulating layer may include an oxide layer, a nitride layer, a carbonization layer, a polymer, or a combination thereof.

The interposer wiring structure 460 may include a plurality of interposer wiring line patterns 462, a plurality of interposer wiring vias 464, and an interposer wiring insulating layer 466. In some embodiments, the interposer wiring structure 460 may be formed by a redistribution process.

The interposer wiring line pattern 462 and the plurality of interposer wiring vias 464 may each be formed of a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), etc., or an alloy thereof but is not limited thereto. In some embodiments, the plurality of interposer wiring line patterns 462 and the plurality of interposer wiring vias 464 may each be formed by stacking a metal or a metal alloy on a seed layer including titanium, titanium nitride, or titanium tungsten. The plurality of interposer wiring line patterns 462 may be on at least one of an upper surface and a lower surface of the interposer wiring insulating layer 466. The plurality of interposer wiring vias 464 may penetrate the interposer wiring insulating layer 466 to be respectively connected to some of the plurality of interposer wiring line patterns 462. In some embodiments, at least some of the plurality of interposer wiring line patterns 462 may be formed together with some of the plurality of interposer wiring vias 464 to respectively form one body. For example, the plurality of interposer wiring line patterns 462 may be respectively integral with the plurality of interposer wiring vias 464 respectively contacting lower surfaces of the plurality of interposer wiring line patterns 462. In some embodiments, the plurality of interposer wiring vias 464 may have a tapered shape extending and having an increasing horizontal width from a lower side to an upper side of each of the plurality of interposer wiring vias 464. That is, horizontal widths of the plurality of interposer wiring vias 464 may increase as a distance from the package base substrate 600 increases.

The interposer wiring insulating layer 466 may be formed of, for example, photo imageable dielectric (PID) or photosensitive polyimide (PSPI). In some embodiments, the interposer wiring structure 460 may include a plurality of stacked interposer wiring insulating layers 466.

In some embodiments, the interposer wiring structure 460 may be formed by a semiconductor back end of line (BEOL) process. The plurality of interposer wiring line patterns 462 and the plurality of interposer wiring vias 464 may each be formed of a metal material, such as copper (Cu), aluminum (Al), or tungsten (W). The interposer wiring insulation layer 466 may be formed of a high density plasma (HDP) oxide layer, a tetra-ethyl orthosilicate (TEOS) oxide layer, tonen silazene (TOSZ), spin on glass (SOG), undoped silica glass (USG), a low-k dielectric layer, etc.

Some of the plurality of interposer wiring line patterns 462 on an upper surface of the interposer 400 may be referred to as interposer upper surface pads. A plurality of first chip connection terminals 150 and a plurality of third chip connection terminals 550 may be respectively bonded to the interposer upper surface pads. In some embodiments, the plurality of first chip connection terminals 150 and the plurality of third chip connection terminals 550 may each be a bump, a solder ball, etc. A first underfill layer 180 surrounding or at least partially surrounding the plurality of first chip connection terminals 150 may be between the interposer 400 and the semiconductor stacked structure 1, and a second underfill layer 580 surrounding or at least partially surrounding the plurality of third chip connection terminals 550 may be between the interposer 400 and the third semiconductor chip 500. The first underfill layer 180 and the second underfill layer 580 may be formed of, for example, an epoxy resin formed by a capillary under-fill method. In some embodiments, the first underfill layer 180 and the second underfill layer 580 may be a non-conductive film (NCF).

The semiconductor stacked structure 1 may include the first semiconductor chip 100, the plurality of second semiconductor chips 200, and at least one passive device 310. Although FIG. 1 illustrates that the semiconductor stacked structure 1 includes one first semiconductor chip 100 and four second semiconductor chips 200, the semiconductor stacked structure 1 is not limited thereto. For example, the semiconductor stacked structure 1 may include two or more second semiconductor chips 200. In some embodiments, the semiconductor stacked structure 1 may include a multiple of 4 second semiconductor chips 200. The plurality of second semiconductor chips 200 may be sequentially stacked on the first semiconductor chip 100 in the vertical direction.

The first semiconductor chip 100 and the plurality of second semiconductor chips 200 may include dynamic random access memory (DRAM), static random access memory (SRAM), flash memory, electrically erasable memory and programmable read-only memory (EEPROM), phase-change random access memory (PRAM), magnetic random access memory (MRAM), and resistive random access memory (RRAM).

In some embodiments, the first semiconductor chip 100 may not include memory cells. The first semiconductor chip 100 may include a test logic circuit, such as a serial-parallel conversion circuit, a design for test (DFT), a joint test action group (JTAG), or a memory built-in self-test (MBIST), and may include a signal interface circuit, such as PHY. The plurality of second semiconductor chips 200 may each include memory cells. For example, the first semiconductor chip 100 may be a buffer chip for controlling the plurality of second semiconductor chips 200.

In some embodiments, the first semiconductor chip 100 may be a buffer chip for controlling high bandwidth memory (HBM) DRAM, and the plurality of second semiconductor chips 200 may be memory cell chips each having HBM DRAM cells controlled by the first semiconductor chip 100. The first semiconductor chip 100 may be referred to as a buffer chip or a master chip, and the plurality of second semiconductor chips 200 may each be referred to as a slave chip or a memory cell chip. The semiconductor stacked structure 1 including the first semiconductor chip 100 and the plurality of second semiconductor chips 200 sequentially stacked on the first semiconductor chip 100 may be referred to as an HBM DRAM device.

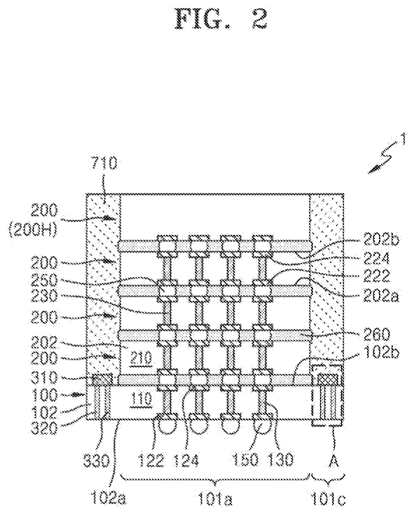

FIG. 2 is a cross-sectional view illustrating a semiconductor stacked structure according to one or more embodiments. The first semiconductor chip 100 may include a first semiconductor substrate 102, a plurality of first front connection pads 122, a plurality of first rear connection pads 124, and a plurality of first through-electrodes 130. The plurality of second semiconductor chips 200 may each include a second semiconductor substrate 202, a plurality of second front connection pads 222, a plurality of second rear connection pads 224, and a plurality of second through-electrodes 230.

The passive device 310 may be on the first semiconductor chip 100, and the first semiconductor chip 100 may include a third through-electrode 320 and a fourth through-electrode 330.

The first semiconductor substrate 102 and the second semiconductor substrate 202 may each include silicon (Si). Alternatively, the first semiconductor substrate 102 and the second semiconductor substrate 202 may each include a semiconductor element, such as germanium (Ge), or a compound semiconductor, such as silicon carbide (SiC), gallium arsenide (GaAs), indium arsenide (InAs), or indium phosphide (InP). The first semiconductor substrate 102 and the second semiconductor substrate 202 may each have an active surface and an inactive surface opposite to the active surface. In some embodiments, an inactive surface 102b of the first semiconductor substrate 102 may be an upper surface of the first semiconductor substrate 102 facing the second semiconductor chip 200, and an active surface 102a of the first semiconductor substrate 102 may be a lower surface of the first semiconductor substrate 102. In each of the first semiconductor substrate 102 and the second semiconductor substrate 202, the active surface may include a plurality of individual devices. The plurality of individual devices may include various microelectronics devices, such as a metal-oxide-semiconductor field effect transistor (MOSFET) such as a complementary metal-insulator-semiconductor (CMOS) transistor, a system large scale integration (LSI), an image sensor such as CMOS imaging sensor (CIS), a micro-electro-mechanical system (MEMS), an active device, and a passive device. The active surface 102a and an inactive surface 102b of the first semiconductor substrate 102 may be respectively referred to as a first active surface and a first inactive surface, and an active surface and an inactive surface of the second semiconductor substrate 202 may be respectively referred to as a second active surface (e.g., 202a) and a second inactive surface (e.g., 202b).

The first semiconductor chip 100 and each of the plurality of second semiconductor chips 200 may respectively include a first semiconductor device 110 and a second semiconductor device 210 respectively composed of a plurality of individual devices. The plurality of first front connection pads 122 and the plurality of first rear connection pads 124 may be respectively on the first active surface 102a and the first inactive surface 102b of the first semiconductor substrate 102. In addition, the plurality of first through-electrodes 130 may vertically penetrate at least a portion of the first semiconductor substrate 102 to electrically and respectively connect the plurality of first front connection pads 122 to the plurality of first rear connection pads 124.

The second semiconductor device 210 is formed on the second active surface of the second semiconductor substrate 202, and the plurality of second front connection pads 222 and the plurality of second rear connection pads 224 may be respectively formed on the second active surface (e.g., 202a) and the second inactive surface (e.g., 202b) of the second semiconductor substrate 202. In addition, the plurality of second through-electrodes 230 may vertically penetrate at least a portion of the second semiconductor substrate 202 to electrically and respectively connect the plurality of second front connection pads 222 to the plurality of second rear connection pads 224. The plurality of second through-electrodes 230 may be electrically and respectively connected to the plurality of first through-electrodes 130.

The semiconductor stacked structure 1 may be electrically connected to the interposer 400 through the plurality of first front connection pads 122. In some embodiments, the plurality of first chip connection terminals 150 may be between the plurality of first front connection pads 122 and a plurality of redistribution upper surface pads among the plurality of interposer wiring line patterns 462 to electrically and respectively connect the plurality of first front connection pads 122 to the plurality of redistribution upper surface pads. A plurality of second chip connection terminals 250 may be respectively bonded to the plurality of second front connection pads 222 of each of the plurality of second semiconductor chips 200. The plurality of second chip connection terminals 250 may be between the plurality of first rear connection pads 124 of the first semiconductor chip 100 and the plurality of second front connection pads 222 of the lowermost second semiconductor chip 200 among the plurality of second semiconductor chips 200, as well as between the plurality of second front connection pads 222 of the other second semiconductor chips 200 among the plurality of second semiconductor chips 200 and the plurality of second rear connection pads 224 of another second semiconductor chip 200 on a lower side of the other second semiconductor chips 200, to electrically connect the first semiconductor chip 100 to the plurality of second semiconductor chips 200. The plurality of second chip connection terminals 250 may be bumps, solder balls, etc.

In some embodiments, a top second semiconductor chip 200H, which is located at the top and is farthest from the first semiconductor chip 100, among the plurality of second semiconductor chips 200, may not include the plurality of second rear connection pads 224 and the plurality of second through-electrodes 230. In some embodiments, a thickness of the top second semiconductor chip 200H, which is located at the top and is farthest from the first semiconductor chip 100 among the plurality of second semiconductor chips 200, may be greater than or equal to a thickness of the other second semiconductor chips 200.

A plurality of insulating adhesive layers 260 may be on the first semiconductor chip 100 and the plurality of second semiconductor chips 200. The insulating adhesive layers 260 may be respectively placed on lower surfaces of the plurality of second semiconductor chips 200 to respectively attach the plurality of second semiconductor chips 200 to lower structures (for example, the first semiconductor chip 100 or other second semiconductor chips 200 on lower sides thereof among the plurality of second semiconductor chips 200). The plurality of insulating adhesive layers 260 may each include an NCF, a non-conductive paste (NCP), an insulating polymer, or an epoxy resin. The plurality of insulating adhesive layers 260 may surround or at least partially surround the plurality of second chip connection terminals 250 and fill spaces between the first semiconductor chip 100 and the plurality of second semiconductor chips 200.

A horizontal width and area of the first semiconductor chip 100 may be greater than a horizontal width and area of each of the plurality of second semiconductor chips 200. For example, the plurality of second semiconductor chips 200 may be above the first semiconductor chip 100 in a vertical direction, and may each have a horizontal width (e.g., a cross-sectional width) that is within a horizontal width of the first semiconductor chip 100. In some embodiments, the plurality of second semiconductor chips 200 may be stacked on each other in the vertical direction.

The semiconductor stacked structure 1 may further include a chip molding layer 710 surrounding or at least partially surrounding the plurality of second semiconductor chips 200 and the plurality of insulating adhesive layers 260 on an upper surface of the first semiconductor chip 100 (that is, the first inactive surface of the first semiconductor substrate 102). The chip molding layer 710 may cover or at least partially cover the upper surface of the first semiconductor chip 100 (that is, the first inactive surface of the first semiconductor substrate 102) and may cover or at least partially cover side surfaces of the plurality of second semiconductor chips 200. In some embodiments, a side surface of the first semiconductor chip 100 and a side surfaces of the chip molding layer 710, which correspond to each other, may be vertically aligned with each other on the same plane. In some embodiments, the chip molding layer 710 may cover or at least partially cover side surfaces of the plurality of second semiconductor chips 200, and may expose an upper surface of the top second semiconductor chip 200H, (that is, an inactive surface of the second semiconductor substrate 202 of the top second semiconductor chip 200H) without covering the upper surface of the top second semiconductor chip 200H. In other words, the chip molding layer 710 may be on the same plane as the upper surface of the top second semiconductor chip 200H. The chip molding layer 710 may be formed of, for example, an epoxy molding compound (EMC).

The third semiconductor chip 500 may include a third semiconductor substrate 502 and a plurality of third front connection pads 520. The plurality of third front connection pads 520 may be on a third active surface of the third semiconductor substrate 502. Because the third semiconductor substrate 502 is substantially similar to the first semiconductor substrate 102 and the second semiconductor substrate 202, detailed descriptions thereof may be omitted. The third semiconductor substrate 502 may have an active surface and an inactive surface opposite to the active surface. The active surface and inactive surface of the third semiconductor substrate 502 may be respectively referred to as a third active surface and a third inactive surface. The third semiconductor chip 500 may include a third semiconductor device 510.

The third semiconductor chip 500 may be electrically connected to the interposer 400 through the plurality of third front connection pads 520. In some embodiments, a plurality of third chip connection terminals 550 may be between the plurality of third front connection pads 520 and a plurality of interposer upper surface pads to electrically and respectively connect the plurality of third front connection pads 520 to a plurality of redistribution upper surface pads.

The third semiconductor chip 500 may include one of, for example, a central processing unit (CPU) chip, a graphics processing unit (GPU) chip, an application processor (AP) chip, an application specific integrated circuit (ASIC), and other processing chips.

The semiconductor package 1000 may further include the package molding layer 720 surrounding or at least partially surrounding the semiconductor stacked structure 1 and at least one third semiconductor chip 500 on the interposer 400. The package molding layer 720 may be formed of, for example, EMC. In some embodiments, the package molding layer 720 may not cover an upper surface of the top second semiconductor chip 200H and an upper surface of at least one third semiconductor chip 500. For example, the package molding layer 720 may cover or at least partially cover a side surface of at least one third semiconductor chip 500. In some embodiments, the package molding layer 720 may cover or at least partially cover a side surface of the chip molding layer 710 surrounding or at least partially surrounding the plurality of second semiconductor chips 200 included in the semiconductor stacked structure 1, and a side surface of the first semiconductor chip 100 included in the semiconductor stacked structure 1. For example, the upper surface of the top second semiconductor chip 200H, the upper surface of the third semiconductor chip 500, the upper surface of the chip molding layer 710, and the upper surface of the package molding layer 720 may be on the same plane. In some embodiments, a side surface of the interposer 400 and a side surface of the package molding layer 720, which correspond to each other, may be aligned with each other in the vertical direction to form the same plane.

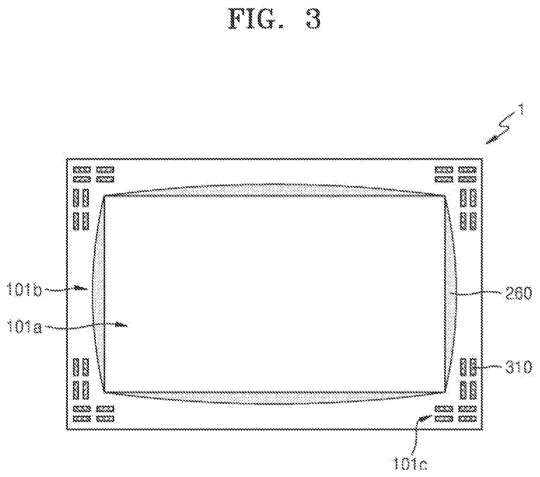

FIG. 3 is a plan view illustrating a semiconductor stacked structure according to one or more embodiments.

Referring to FIGS. 2 and 3, the semiconductor stacked structure 1 may include a first semiconductor chip 100 including a first semiconductor substrate 102 and first through-electrodes 130 penetrating the first semiconductor substrate 102. The semiconductor stacked structure 1 may include a plurality of second semiconductor chips 200 that are sequentially stacked on a central region 101a, are electrically connected to the first semiconductor chip 100 and include second semiconductor substrates 202 and second through-electrodes 230 penetrating the second semiconductor substrate 202, and a plurality of insulating adhesive layers 260 on the first semiconductor chip 100 and the second semiconductor chips 200. The semiconductor stacked structure 1 may include at least one passive device 310 on the first semiconductor chip 100. The first semiconductor chip 100 may have a central region 101a and an outer region 101b surrounding or at least partially surrounding the central region 101a. The at least one passive device 310 may be in a corner region 101c of the outer region 101b of the first semiconductor chip 100. The first semiconductor chip 100 may include the first through-electrodes 130 in the central region 101a.

Although FIG. 2 illustrates that the semiconductor stacked structure 1 includes one first semiconductor chip 100 and four second semiconductor chips 200, the embodiments are not limited thereto. For example, the semiconductor stacked structure 1 may include two or more second semiconductor chips 200. In some embodiments, the semiconductor stacked structure 1 may include a multiple of 4 second semiconductor chips 200. The plurality of second semiconductor chips 200 may be sequentially stacked on the first semiconductor chip 100 in a vertical direction. The first semiconductor chip 100 and the plurality of second semiconductor chips 200 may be sequentially stacked with active surfaces thereof facing downward. The first semiconductor chip 100 may include an input/output buffer (I/O Buffer) or a logic chip, and the plurality of second semiconductor chips 200 may each include a memory semiconductor chip. A size of the first semiconductor chip 100 may be greater than sizes of the plurality of second semiconductor chips 200.

The central region 101a may refer to a region in which the plurality of second semiconductor chips 200 are positioned above the first semiconductor chip 100 in the vertical direction. The outer region 101b may refer to a region in which the plurality of second semiconductor chips 200 are not positioned above the first semiconductor chip 100 in the vertical direction. That is, the plurality of second semiconductor chips 100 may not horizontally extend into the outer region 101b. The outer region 101b may surround or at least partially surround the central region 101a. The corner region 101c may refer to corners of the outer region 101b in a plan view.

The first semiconductor chip 100 may further include a third through-electrode 320 and a fourth through-electrode 330. The third through-electrode 320 and the fourth through-electrode 330 may vertically penetrate at least a portion of the first semiconductor chip 100. The first semiconductor chip 100 may further include the third through-electrode 320 and the fourth through-electrode 330 in the outer region 101b. The first semiconductor chip 100 may further include the third through-electrode 320 and the fourth through-electrode 330 in the corner region 101c.

Referring to FIG. 3, the passive device 310 may include a plurality of passive devices arranged in the outer region 101b of the first semiconductor chip 100. The passive device 310 may include a plurality of passive devices arranged in the corner region 101c of the outer region 101b of the first semiconductor chip 100. Although FIG. 3 illustrates that the semiconductor stacked structure 1 includes 32 passive devices 310, the embodiments are not limited thereto. For example, the semiconductor stacked structure 1 may include two or more passive devices 310. The passive device 310 may include a capacitor. The capacitor may include a plurality of capacitors. The plurality of capacitors may be connected in parallel. The passive device 310 may transmit power to other components.

The semiconductor stacked structure 1 may include insulating adhesive layers 260 arranged on the first semiconductor chip 100 and the plurality of second semiconductor chips 200. In one embodiment, the insulating adhesive layers 260 may respectively protrude between the first semiconductor chip 100 and the plurality of second semiconductor chips 200 to extend into the outer region 101b of the first semiconductor chip 100, and the passive device 310 may be in the corner region 101c of the first semiconductor chip 100 such that the insulating adhesive layer 260 does not extend over the passive device 310 in the vertical direction. The passive device 310 may be in the corner region 101c of the first semiconductor chip 100, where power transmission is weak, to reduce power transmission noise.

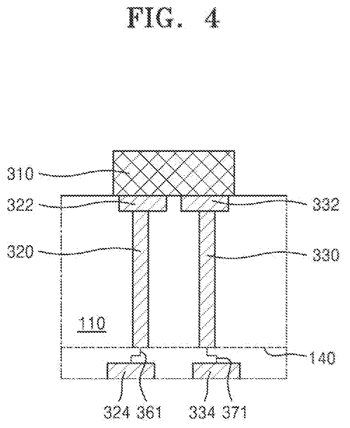

FIG. 4 is a partially enlarged view illustrating a modified example of the semiconductor stacked structure 1 of FIG. 2 according to one or more embodiments. Specifically, FIG. 4 is an enlarged cross-sectional view of a modified example of a portion A of the first semiconductor chip 100 of FIG. 2.

Referring to FIG. 4, the first semiconductor chip 100 may include a third front connection pad 322, a third rear connection pad 324, a third through-electrode 320, a fourth through-electrode 330, a fourth front connection pad 332, a fourth rear connection pad 334, a first power wire 361, and a first ground wire 371. A passive device 310 may be on the first semiconductor chip 100.

The third through-electrode 320 may vertically penetrate at least a portion of the first semiconductor chip 100 in an outer region of the first semiconductor chip 100 to electrically connect the third front connection pad 322 to the third rear connection pad 324. Power may be supplied to the third through-electrode 320. The first semiconductor chip 100 may include the first power wire 361 on an active surface 140. The first power wire 361 may be electrically connected to the third through-electrode 320. The passive device 310 may be electrically connected to the third through-electrode 320 of the first semiconductor chip 100 and the first power wire 361.

The fourth through-electrode 330 may vertically penetrate at least a portion of the first semiconductor chip 100 in an outer region of the first semiconductor chip 100 to electrically connect the fourth front connection pad 332 to the fourth rear connection pad 334. The fourth through-electrode 330 may be grounded. The first semiconductor chip 100 may include the first ground wire 371 on the active surface 140. The first ground wire 371 may be electrically connected to the fourth through-electrode 330. The passive device 310 may be electrically connected to the fourth through-electrode 330 of the first semiconductor chip 100 and the first ground wire 371.

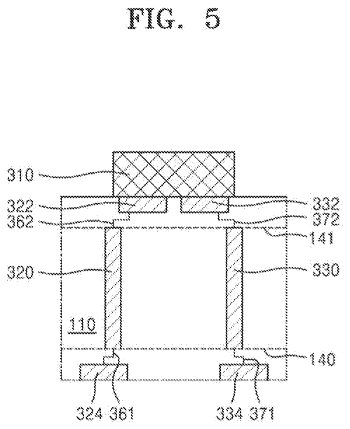

FIG. 5 is a partially enlarged view illustrating a modified example of the semiconductor stacked structure 1 of FIG. 2 according to one or more embodiments. Specifically, FIG. 5 is an enlarged cross-sectional view of a modified example of a portion A of the first semiconductor chip 100 of FIG. 2.

Referring to FIG. 5, the first semiconductor chip 100 may include a third front connection pad 322, a third rear connection pad 324, a third through-electrode 320, a fourth through-electrode 330, a fourth front connection pad 332, a fourth rear connection pad 334, a first power wire 361, a first ground wire 371, a second power wire 362, and a second ground wire 372, and a passive device 310 may be on the first semiconductor chip 100.

The third through-electrode 320 may vertically penetrate at least a portion of the first semiconductor chip 100 in an outer region of the first semiconductor chip 100 to electrically connect the third front connection pad 322 to the third rear connection pad 324. Power may be supplied to the third through-electrode 320. The first semiconductor chip 100 may include the first power wire 361 on an active surface 140. The first semiconductor chip 100 may include the second power wire 362 on an inactive surface 141. The first power wire 361 and the second power wire 362 may be electrically connected to the third through-electrode 320. The passive device 310 may be connected to the third through-electrode 320 of the first semiconductor chip 100, the first power wire 361, and the second power wire 362.

The fourth through-electrode 330 may vertically penetrate at least a portion of the first semiconductor chip 100 in the outer region of the first semiconductor chip 100 to electrically connect the fourth front connection pad 332 to the fourth rear connection pad 334. The fourth through-electrode 330 may be grounded. The first semiconductor chip 100 may include the first ground wire 371 on the active surface 140. The first semiconductor chip 100 may include the second ground wire 372 on the inactive surface 141. The first ground wire 371 and the second ground wire 372 may be electrically connected to the fourth through-electrode 330. The passive device 310 may be connected to the fourth through-electrode 330 of the first semiconductor chip 100, the first ground wire 371, and the second ground wire 372.

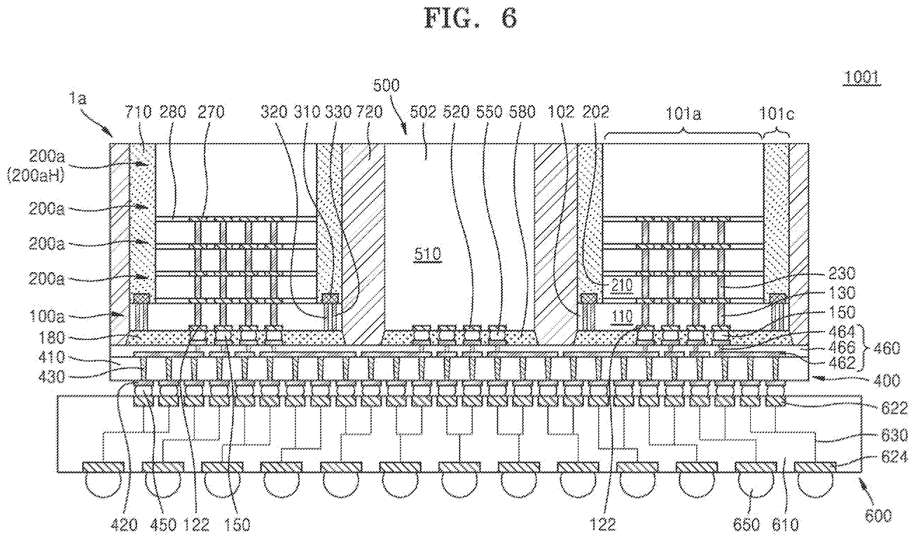

FIG. 6 is a cross-sectional view illustrating a semiconductor package according to one or more embodiments.

In FIG. 6, the same reference numerals as in FIGS. 1 to 3 indicate the same components, and descriptions that are the same as those given with reference to FIGS. 1 to 5 may be omitted.

Referring to FIG. 6, a semiconductor package 1001 may include a package base substrate 600, an interposer 400 attached to the package base substrate 600, and a semiconductor stacked structure 1a attached to the interposer 400. The semiconductor stacked structure 1a may include a first semiconductor chip 100a which has a central region 101a and an outer region 101b surrounding or at least partially surrounding the central region 101a and that includes a first semiconductor substrate 102 and a plurality of first through-electrodes 130 penetrating the first semiconductor substrate 102, a plurality of second semiconductor chips 200 that are electrically connected to the first semiconductor chip 100a in the central region 101a and are sequentially stacked on the first semiconductor chip 100a in the vertical direction and that include second semiconductor substrates 202 and a plurality of second through-electrodes 230 penetrating the second semiconductor substrates 202 and electrically connected to the plurality of second through-electrodes 230, and at least one passive device 310 in a corner region 101c of the outer region 101b of the first semiconductor chip 100a, and at least one third semiconductor chip 500 attached to the interposer 400. The at least one semiconductor stacked structure 1a and the at least one third semiconductor chip 500 may be spaced apart from each other in the horizontal direction and attached to the interposer 400.

The first semiconductor chip 100a may include the first semiconductor substrate 102 and the plurality of first through-electrodes 130, and a plurality of second semiconductor chips 200a may each include the second semiconductor substrate 202 and the plurality of second through-electrodes 230.

The semiconductor stacked structure 1a may include the first semiconductor chip 100a and the plurality of second semiconductor chips 200a. The plurality of second semiconductor chips 200a may be sequentially stacked on the first semiconductor chip 100a in the vertical direction. The first semiconductor chip 100a and the plurality of second semiconductor chips 200a may be electrically connected to each other through a plurality of bonding pads 270 to exchange signals and provide power and ground. For example, the plurality of bonding pads 270 may be between the first semiconductor chip 100a and the lowermost second semiconductor chip 200a, and between two adjacent second semiconductor chips 200a among the plurality of second semiconductor chips 200a.

For example, the plurality of bonding pads 270 may be formed of a material including Cu. The plurality of bonding pads 270 may electrically and respectively connect the plurality of first through-electrodes 130 to the plurality of second through-electrodes 230.

A plurality of chip bonding insulating layers 280 may be between the first semiconductor chip 100a and the plurality of second semiconductor chips 200a. The plurality of bonding pads 270 may be surrounded or at least partially surrounded by the plurality of chip bonding insulating layers 280 between the first semiconductor chip 100a and the plurality of second semiconductor chips 200a (that is, between the first semiconductor chip 100a and the lowermost second semiconductor chip 200a), and between the plurality of second semiconductor chips 200a. The plurality of bonding pads 270 may penetrate the plurality of chip bonding insulating layers 280. The plurality of chip bonding insulating layers 280 may be between the first semiconductor chip 100a and the plurality of second semiconductor chips 200a.

The plurality of bonding pads 270 may be formed by separately forming conductive material layers on surfaces that face each other, of two adjacent chips among the first semiconductor chip 100a and the plurality of second semiconductor chips 200a, and then by causing the conductive material layers facing each other to perform diffusion-bonding, expanding by heat, coming into contact with each other, and being integrated through diffusion of metal atoms contained therein.

The chip bonding insulating layer 280 may be formed by separately forming insulating material layers on surfaces that face each other, of two adjacent chips among the first semiconductor chip 100a and the plurality of second semiconductor chips 200a, and then by causing the insulating material layers facing each other to perform diffusion-bonding in a process of forming the plurality of bonding pads 270, expanding by heat, coming into contact with each other, and being integrated through diffusion of atoms contained therein.

The plurality of chip bonding insulating layers 280 may cover or at least partially cover upper surfaces and lower surfaces of the second semiconductor chips 200a facing each other along with the plurality of bonding pads 270. The plurality of chip bonding insulating layers 280 may each have flat upper and lower surfaces to have substantially the same thickness.

The plurality of chip bonding insulating layers 280 may each be formed of any one of SiO, SiN, SiCN, SiCO, and a polymer material. The polymer material may include benzocyclobutene (BCB), polyimide (PI), polybenzoxazole (PBO), silicone, acrylate, or epoxy. For example, the plurality of chip bonding insulating layers 280 may each be formed of silicon oxide. The plurality of chip bonding insulating layers 280 may each have a thickness of, for example, about 100 nm to about 1 μm.

The first semiconductor chip 100a and the plurality of second semiconductor chips 200a may be stacked by hybrid bonding caused by diffusion bonding of the plurality of bonding pads 270 and the plurality of chip bonding insulating layers 280.

The semiconductor stacked structure 1a may further include a chip molding layer 710 surrounding or at least partially surrounding the plurality of second semiconductor chips 200a and the plurality of chip bonding insulating layers 280 on the first semiconductor chip 100a. In some embodiments, the chip molding layer 710 may cover or at least partially cover side surfaces of the plurality of second semiconductor chips 200a and may expose an upper surface of a top second semiconductor chip 200aH without covering the upper surface of the top second semiconductor chip 200aH.

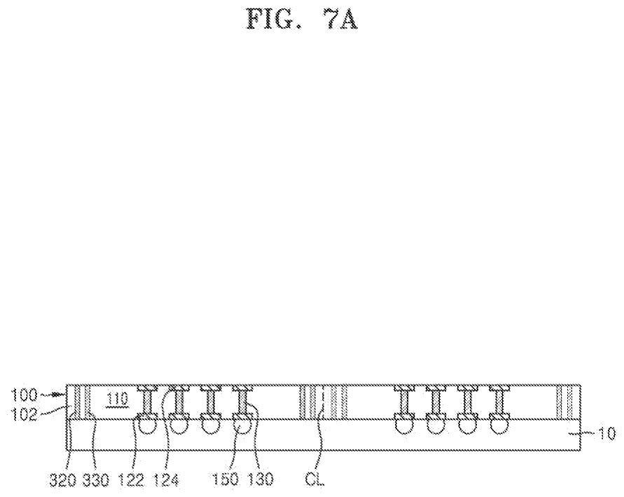

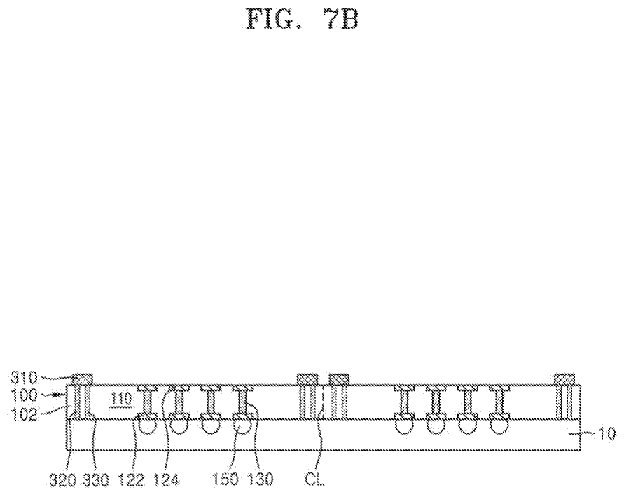

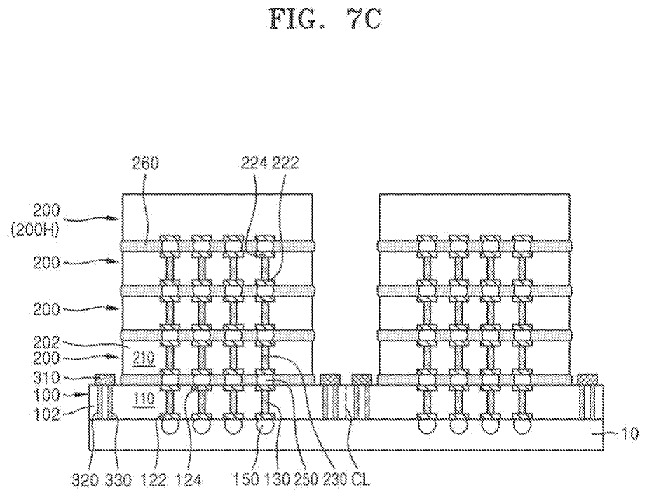

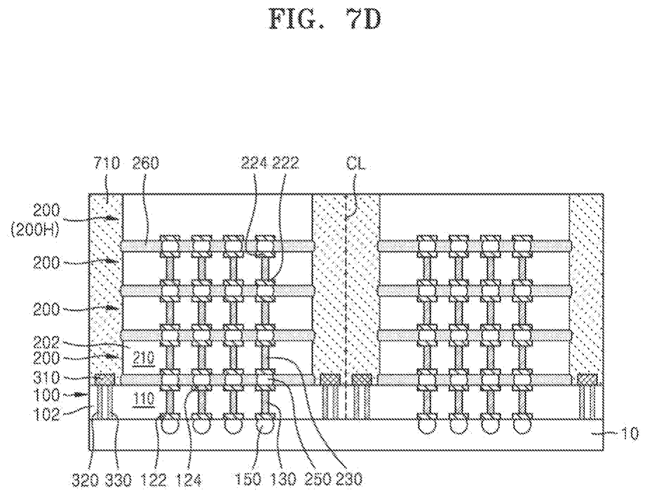

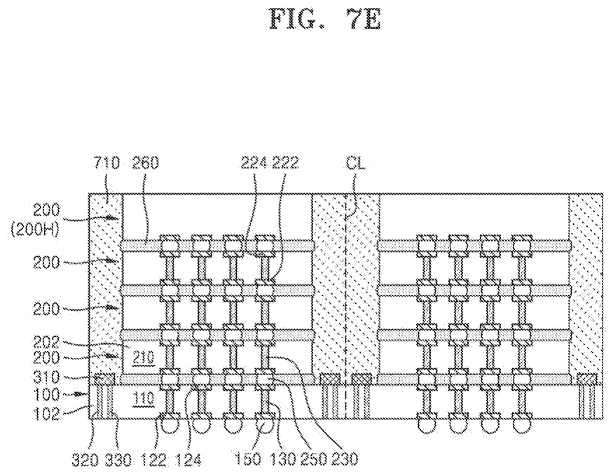

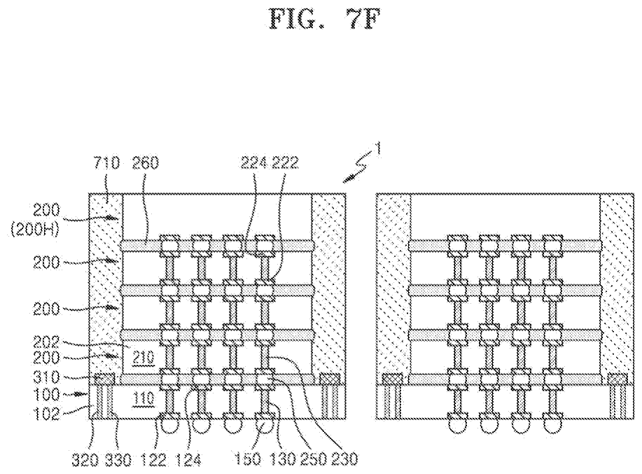

FIGS. 7A to 7F are cross-sectional views illustrating a method of manufacturing a semiconductor stacked structure, according to one or more embodiments. Hereinafter, the method of manufacturing the semiconductor stacked structure described with reference to FIG. 2 will be described with reference to FIGS. 7A to 7F.

Referring to FIG. 7A, a semiconductor wafer 10 may be prepared, and a plurality of first chip connection terminals 150 and the first semiconductor chip 100 are on the semiconductor wafer 10. The first semiconductor chip 100 may include the first semiconductor substrate 102, a plurality of first front connection pads 122, a plurality of first rear connection pads 124, a plurality of first through-electrodes 130, a plurality of third through-electrodes 320, and a plurality of fourth through-electrodes 330.

Referring to FIG. 7B, a plurality of passive devices 310 may be formed on the first semiconductor chip 100. The plurality of passive devices 310 may be electrically and respectively connected to the plurality of third through-electrodes 320 and the plurality of fourth through-electrodes 330.

Referring to FIG. 7C, the plurality of second semiconductor chips 200 may be mounted on the first semiconductor chip 100. The plurality of second semiconductor chips 200 may each include the second semiconductor substrate 202, a plurality of second front connection pads 222, a plurality of second rear connection pads 224, and a plurality of second through-electrodes 230. The first semiconductor chip 100, may be connected to the plurality of second semiconductor chips 200 through a plurality of second chip connection terminals 250. The plurality of second semiconductor chips 200 may be sequentially stacked on the first semiconductor chip 100 after a plurality of insulating adhesive layers 260 are respectively attached to lower surfaces of the plurality of second semiconductor chips 200.

Referring to FIG. 7D, the chip molding layer 710 may be formed on the first semiconductor chip 100 to surround or at least partially surround the plurality of second semiconductor chips 200 and the plurality of insulating adhesive layers 260. A side surface of the chip molding layer 710 and a side surface of the first semiconductor chip 100 corresponding to the side surface of the chip molding layer 710 may be vertically aligned with each other on the same plane. Also, a portion of an upper portion of the chip molding layer 710 may be removed. In one embodiment, the upper portion of the chip molding layer 710 may be removed by a grinding process. For example, the upper portion of the chip molding layer 710 may be removed by a grinding process such that the upper surface of the chip molding layer 710 and an upper surface of the top second semiconductor chip 200H are on the same plane. However, the embodiments are not limited thereto, and the grinding process of removing the upper portion of the chip molding layer 710 may be omitted.

Referring to FIG. 7E, the semiconductor wafer 10 under the first semiconductor chip 100 may be removed. The semiconductor wafer 10 may be attached to the first semiconductor chip 100 by glue to be easily removed.

Referring to FIG. 7F, a cutting process may be performed to cut the first semiconductor chip 100 along a cutting line CL. A plurality of semiconductor stacked structures 1 may be formed through the cutting process. The plurality of semiconductor stacked structures 1 may be the same as the semiconductor stacked structures 1 and 1a described with reference to FIGS. 1 to 6.

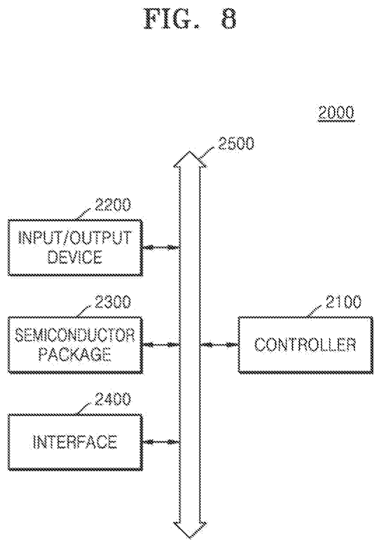

FIG. 8 is a block diagram illustrating an example of a memory system including a semiconductor package according to one or more embodiments.

Referring to FIG. 8, a memory system 2000 may be applied to a personal digital assistant (PDA), a portable computer, a web tablet, a wireless phone, a mobile phone, a digital music player, a memory card, or any device that may transmit and/or receive information to and/or from other devices in a wireless environment.

The memory system 2000 may include a controller 2100, an input/output device 2200 such as a key pad, a keyboard, and a display, a semiconductor package 2300, an interface 2400, and a bus 2500. The semiconductor package 2300 may communicate with the interface 2400 through the bus 2500.

The controller 2100 may include at least one microprocessor, a digital signal processor, a microcontroller, or other processing devices similar thereto. The semiconductor package 2300 may be used to store commands performed by the controller 2100. The input/output device 2200 may receive data or signals from the outside of the memory system 2000 or output data or signals to the outside of the memory system 2000.

The semiconductor package 2300 may include the semiconductor packages 1000 and 1001 described with reference to FIGS. 1 and 6 and the semiconductor stacked structures 1 and 1a described with reference to FIGS. 1 to 6. The semiconductor package 2300 may be a memory chip package. The memory chip package may include a volatile memory chip and/or a non-volatile memory chip. The interface 2400 may transmit data to a communication network or receive data from the communication network.

According to the disclosure, a semiconductor stacked structure may include a passive device therein to transmit high-speed signals without noise, and particularly includes the passive device in a corner region of a first semiconductor chip where signal transmission is weak, and thus, signal transmission speed may be increased.

Therefore, a semiconductor stacked structure and a semiconductor package including the same, according to the disclosure, may transmit high-speed signals without noise and increase a signal transmission speed.

At least one of the devices, units, components, modules, units, or the like represented by a block or an equivalent indication in the above embodiments including, but not limited to, FIG. 8, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor stacked structure, comprising:
a first semiconductor chip comprising:
a central region;
an outer region at least partially surrounding the central region, the outer region comprising a corner region; and
a first through-electrode in the central region;
a plurality of second semiconductor chips sequentially stacked in the central region and connected to the first semiconductor chip, each of the plurality of second semiconductor chips comprising a second through-electrode; and
at least one passive device in the corner region of the outer region.

2. The semiconductor stacked structure of claim 1, further comprising:
a first insulating adhesive layer on the first semiconductor chip; and
a plurality of second insulating adhesive layers respectively on the plurality of second semiconductor chips,
wherein each of the first insulating adhesive layer and the plurality of second insulating adhesive layers extends into the outer region, and
wherein each of the first insulating adhesive layer and the plurality of second insulating adhesive layers does not extend over the at least one passive device in the corner region of the outer region.

3. The semiconductor stacked structure of claim 2, wherein the first insulating adhesive layer and the plurality of second insulating adhesive layers comprise a non-conductive film (NCF), a non-conductive paste (NCP), an insulating polymer, or an epoxy resin.

4. The semiconductor stacked structure of claim 1, wherein the first semiconductor chip further comprises a third through-electrode in the corner region of the outer region, and
wherein the at least one passive device is connected to the third through-electrode.

5. The semiconductor stacked structure of claim 4, wherein the first semiconductor chip further comprises an active surface and a first power wire on the active surface, and
wherein the at least one passive device is connected to the first power wire.

6. The semiconductor stacked structure of claim 5, wherein the first semiconductor chip further comprises an inactive surface and a second power wire on the inactive surface, and
wherein the at least one passive device is connected to the second power wire.

7. The semiconductor stacked structure of claim 4, wherein the first semiconductor chip further comprises a fourth through-electrode in the corner region of the outer region, the fourth through-electrode is configured to be grounded,
wherein the third through-electrode is configured to receive supplied power, and
wherein the at least one passive device is connected to the fourth through-electrode of the first semiconductor chip.

8. The semiconductor stacked structure of claim 7, wherein the first semiconductor chip further comprises an active surface and a first ground wire on the active surface, and
wherein the at least one passive device is connected to the first ground wire.

9. The semiconductor stacked structure of claim 8, wherein the first semiconductor chip further comprises an inactive surface and a second ground wire on the inactive surface, and
wherein the at least one passive device is connected to the second ground wire.

10. The semiconductor stacked structure of claim 1, wherein the first semiconductor chip comprises at least one of an input/output buffer and a logic chip, and
wherein each of the plurality of second semiconductor chips comprises a memory semiconductor chip.

11. The semiconductor stacked structure of claim 1, further comprising:
a chip molding layer on the first semiconductor chip and at least partially surrounding the plurality of second semiconductor chips,
wherein a side surface of the chip molding layer is vertically aligned with and on the same plane as a side surface of the first semiconductor chip.

12. A semiconductor stacked structure, comprising:
a first semiconductor chip comprising:
a central region;
an outer region at least partially surrounding the central region, the outer region comprising a corner region; and
a plurality of first through-electrodes in the central region and penetrating the first semiconductor chip;
a plurality of second semiconductor chips sequentially stacked on the first semiconductor chip in the central region and connected to the first semiconductor chip, each of the plurality of second semiconductor chips comprising:
a second semiconductor substrate; and
a plurality of second through-electrodes penetrating the second semiconductor substrate and respectively connected to the plurality of first through-electrodes;
at least one passive device in the corner region of the outer region; and
a chip molding layer on the first semiconductor chip and at least partially surrounding the plurality of second semiconductor chips.

13. The semiconductor stacked structure of claim 12, further comprising:
a first insulating adhesive layer on the first semiconductor chip; and
a plurality of second insulating adhesive layers respectively on the plurality of second semiconductor chips,
wherein each of the first insulating adhesive layer and the plurality of second insulating adhesive layers extends into the outer region, and
wherein each of the first insulating adhesive layer and the plurality of second insulating adhesive layers does not extend over the at least one passive device in the corner region of the outer region.

14. The semiconductor stacked structure of claim 12, wherein the first semiconductor chip further comprises:
a third through-electrode in the corner region of the outer region and configured to receive supplied power; and
a fourth through-electrode in the corner region of the outer region and configured to be grounded, and
wherein the at least one passive device is connected to the third through-electrode and the fourth through-electrode.

15. The semiconductor stacked structure of claim 14, wherein the first semiconductor chip comprises:
an active surface;
a first power wire and a first ground wire on the active surface;
an inactive surface; and
a second power wire and a second ground wire on the inactive surface, and
wherein the at least one passive device is connected to the first power wire, the second power wire, the first ground wire, and the second ground wire.

16. A semiconductor package comprising:
a package base substrate;
an interposer on the package base substrate and connected to the package base substrate, the interposer comprising:
a base layer; and
a plurality of interposer through-electrodes penetrating the base layer;
at least one semiconductor stacked structure on the interposer, the at least one semiconductor stacked structure comprising:
a first semiconductor chip comprising:
a central region; and
an outer region at least partially surrounding the central region, the outer region comprising a corner region; and
a first through-electrode in the central region;
a plurality of second semiconductor chips sequentially stacked on the first semiconductor chip in the central region and connected to the first semiconductor chip, each of the plurality of second semiconductor chips comprising a second through-electrode;
at least one passive device in the corner region of the outer region; and
a chip molding layer on an upper surface of the first semiconductor chip and at least partially covering side surfaces of the plurality of second semiconductor chips;
at least one third semiconductor chip on the interposer and horizontally spaced apart from the at least one semiconductor stacked structure; and
a package molding layer on the interposer and at least partially surrounding the at least one semiconductor stacked structure and the at least one third semiconductor chip,
wherein the package molding layer is configured to form a molding interface with the chip molding layer.

17. The semiconductor package of claim 16, further comprising:
a first insulating adhesive layer on the first semiconductor chip; and
a plurality of second insulating adhesive layers respectively on the plurality of second semiconductor chips,
wherein each of the first insulating adhesive layer and the plurality of second insulating adhesive layers extends into the outer region, and
wherein each of the first insulating adhesive layer and the plurality of second insulating adhesive layers does not extend over the at least one passive device.

18. The semiconductor package of claim 16, wherein the plurality of second semiconductor chips comprise a top second semiconductor chip,
wherein an upper surface of the top second semiconductor chip, an upper surface of the at least one third semiconductor chip, an upper surface of the chip molding layer, and an upper surface of the package molding layer are on the same plane, and
wherein a horizontal width of the first semiconductor chip is greater than horizontal widths of the plurality of second semiconductor chips.

19. The semiconductor package of claim 16, wherein the first semiconductor chip further comprises:
a third through-electrode in the corner region of the outer region and configured to receive supplied power; and
a fourth through-electrode in the corner region of the outer region and configured to be grounded, and
wherein the at least one passive device is connected to the third through-electrode and the fourth through-electrode.

20. The semiconductor package of claim 16, wherein the first semiconductor chip comprises:
an active surface;
a first power wire and a first ground wire on the active surface;
an inactive surface; and
a second power wire and a second ground wire on the inactive surface, and
wherein the at least one passive device is connected to the first power wire, the second power wire, the first ground wire, and the second ground wire.
